(19) United States
(12) Patent Application Publication
(10) Pub. No.: US 2014/0376185 A1
(43) Pub. Date: Dec. 25, 2014

(54) COOLING DEVICE

(71) Applicant: Fairchild Korea Semiconductor LTD., Bucheon-si (KR)

(72) Inventors: Youngsik LEE, Seoul (KR); Sangtae IM, Bucheon-si (KR); Jong-Soo CHO, Seoul (KR); Seungpil YOO, Incheon (KR); Jinyong LEE, Seoul (KR); Boyoung LEE, Seoul (KR)

(21) Appl. No.: 14/303,801

(22) Filed: Jun. 13, 2014

Related U.S. Application Data
(60) Provisional application No. 61/836,907, filed on Jun. 19, 2013.

(30) Foreign Application Priority Data
May 30, 2014 (KR) 10-2014-0066239

(51) Int. Cl. H05K 7/20; H01L 41/09

(52) U.S. Cl. CPC H05K 7/20136; H01L 41/09
USPC 361/694

(57) ABSTRACT

A cooling device according to an exemplary embodiment of the present invention includes: a chamber including at least one flexible surface; a piezoelectric element formed in the at least one flexible surface and generating a volume change in the chamber by bending the at least one flexible surface in a first direction or a second direction to generates a first directional air flow or a second directional air flow; an opening formed in the chamber and becoming a channel of the first direction air flow or the second directional air flow; and at least one connection unit connected to the outer side of the chamber and the outer side of a heat source that is provided at a distance from the chamber and connecting the chamber and the heat source.

### CROSS-REFERENCE TO RELATED APPLICATION

This application claims priority to and the benefit of U.S. Patent Application No. 61/836,907 filed in the USPTO on Jun. 19, 2013, and priority to and the benefit of Korean Patent Application No. 10-2014-0066239 filed in the Korean Intellectual Property Office on May 30, 2014, the entire contents of which are incorporated herein by reference.

### BACKGROUND

(a) Field

The present invention relates to a cooling device. More particularly, the present invention relates to a cooling device that emits heat generated from an electronic device to the outside using a piezoelectric element.

(b) Description of the Related Art

Recently, an electronic device has been down-sized and thus a semiconductor device has been integrated. Cooling of heat generated due to long-term use of the down-sized electronic device becomes a problem.

For example, a central processing unit (CPU) used in a computer and the like generates a significantly large amount of heat. In order to remove such heat, a conventional cooling means, i.e., a fan-type cooling device, is used.

However, the fan-type cooling device has many problems such as excessive noise, excessive power consumption, difficulty in manufacturing, and difficulty in down-sizing.

The above information disclosed in this Background section is only for enhancement of understanding of the background of the invention and therefore it may contain information that does not form the prior art that is already known in this country to a person of ordinary skill in the art.

### SUMMARY

The present invention has been made in an effort to generate an air flow at a peripheral area of a heat source and optimize a heat emission effect by increasing a heat conductive area.

A cooling device according to an exemplary embodiment of the present invention includes: a chamber including at least one flexible surface; a piezoelectric element formed in the at least one flexible surface and generating a volume change in the chamber by bending the at least one flexible surface in a first direction or a second direction to generates a first directional air flow or a second directional air flow; an opening formed in the chamber and becoming a channel of the first direction air flow or the second directional air flow; and at least one connection unit connected to the outer side of the chamber and the outer side of a heat source that is provided at a distance from the chamber and connecting the chamber and the heat source.

In addition, the first directional air flow and the second directional air flow include a circulation air flow circulating between the chamber and the heat source and cooling heat of the heat source by reaching the chamber, the connecting unit, and the heat source.

In addition, the connection unit is formed of at least two connection members, and an air outlet through which the heat of the heat source is emitted is formed between the at least two connection members.

Further, the connection unit includes protrusions and depressions formed in a surface exposed to the outside. The connection unit is made of a thermally conductive material.

The piezoelectric element is an electric piezoelectric element using a piezoelectric characteristic of a ceramic material, and the electric piezoelectric element bends the at least one flexible surface to the first direction or the second direction by a polarity of an electric signal.

The opening is formed in parallel with the heat source.

The connection unit includes a first member contacting an upper end of the chamber and a second member extended perpendicularly from one of the at least two connection units and contacting one surface of the heat source.

The second member is separated from or contacts one surface of the chamber.

In addition, the cooling device includes a third member perpendicularly connected with the second member and contacting an upper surface or a bottom surface of the heat source.

The connection unit further includes a substrate attachment surface attached to a substrate that includes the heat source and a fourth member extended to the substrate attachment surface and contacts the substrate attachment surface.

In addition, the cooling device includes: at least two piezoelectric elements; a chamber formed of a plurality of surfaces that include a flexible first surface where the at least two piezoelectric elements are formed and a second surface where at least two openings are formed corresponding to locations of the at least two piezoelectric elements; and at least two connection units connecting the chamber and at least two heat sources by being attached to the chamber at the chamber and the at least two heat sources and heat of the at least two heat sources is conducted to the chamber, the first directional air flow and the second directional air flow is formed by the at least two piezoelectric elements and supplied to the heat source through the at least two openings, and a part of the at least two connection units includes a first member connecting an upper end of the chamber and a second member perpendicularly extended from the first member and contacting a heat source that contacts one surface of the heat source.

The connection unit is made of a thermally conductive material, heat from the at least two heat sources is conducted to the chamber through the at least two connection units and emitted through the at least two connection units and the chamber, and the first directional air flow and the second directional air flow emit heat of the heat source by circulating between the at least two connection units.

The chamber includes at least two distinctive spaces respectively corresponding to locations of the at least two heat sources.

The connection unit is formed of an adhesive tape made of a thermally conductive material.

A cooling device according to another exemplary embodiment of the present invention includes: a chamber including at least one flexible surface; a piezoelectric element formed in the at least one flexible surface and generating a volume change in the chamber by bending the at least one flexible surface in a first direction or a second direction to generates a first directional air flow or a second directional air flow; an opening formed in the chamber and becoming a channel of the first direction air flow or the second directional air flow; and a connection unit. The connection unit includes a first member contacting an upper end of the chamber, a second member perpendicularly extended from the first member and contacting one surface of a heat source, and a second member perpendicularly extended from the first member and contacting one surface of a heat source, and the flow path forms an air flow path between the chamber and the heat source.

The first directional air flow and the second directional air flow include a circulation air flow circulating between the chamber and the heat source and cooling heat of the heat source by reaching the chamber, the connecting unit, and the heat source.

The connection unit is made of a thermally conductive material, heat of the heat source is conducted to the chamber through the connection unit, the heat is emitted through the connection unit and the chamber, and the first directional air flow or the second directional air flow is supplied to the heat source through the flow path.

The flow path is formed in parallel with the heat source, and the first directional air flow or the second directional air flow is supplied in a direction parallel to the heat source through the flow path.

The flow path is formed perpendicularly to the heat source, and the first directional air flow or the second directional air flow is supplied to the heat source in a perpendicular direction.

The flow path is formed oblique to the heat source, and the first directional air flow or the second directional air flow is supplied in an oblique direction to the heat source through the flow path.

The flow path includes a corner, and the first direction air flow or the second directional air flow is supplied to the heat source through the flow path.

The flow path includes a curved surface, and the first directional air flow or the second directional air flow is supplied to the heat source through the flow path.

The cooling device according the present invention can optimize heat emission by forming an air flow at the peripheral area of a heat source.

In addition, the cooling device according the present invention can increase a thermal conductive area.

### BRIEF DESCRIPTION OF THE DRAWINGS

FIG. 1 illustrates a cooling device according to a first exemplary embodiment of the present invention.

FIG. 2 is a cross-sectional view of FIG. 1, taken along the line X-Y, and illustrates air flow of the cooling device according to the first exemplary embodiment of the present invention.

FIG. 3 is a cross-sectional view of FIG. 1, taken along the line X-Y, and illustrates air circulation of the cooling device according to the first exemplary embodiment of the present invention.

FIG. 4 is a cross-sectional view of FIG. 1, taken along the line X-Y, and illustrates air flow of the cooling device according to the first exemplary embodiment of the present invention.

FIG. 5 is a cross-sectional view of FIG. 1, taken along the line X′-Y′, and illustrates air circulation of the cooling device according to the first exemplary embodiment of the present invention.

FIG. 6 is a cross-sectional view of FIG. 1, taken along the line X′-Y′, and illustrates air circulation of the cooling device according to the first exemplary embodiment of the present invention.

FIG. 7 is a cross-sectional view of FIG. 1, taken along the line X′-Y′, and illustrates an air flow of the cooling device according to the first exemplary embodiment of the present invention.

FIG. 8 illustrates a cooling device according to a second exemplary embodiment of the present invention.

FIG. 9 illustrates a cooling device according to a third exemplary embodiment of the present invention.

FIG. 10 is a cooling device according to a fourth exemplary embodiment of the present invention.

FIG. 11 is a cooling device according to a fifth exemplary embodiment of the present invention.

FIG. 12 is a cross-sectional view of a cooling device according to a sixth exemplary embodiment of the present invention.

FIG. 13 is a cross-sectional view of a cooling device according to a seventh exemplary embodiment of the present invention.

FIG. 14 is a perspective view of the cooling device according to the seventh exemplary embodiment of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. In addition, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and operation, and can be implemented by hardware components or software components and combinations thereof.

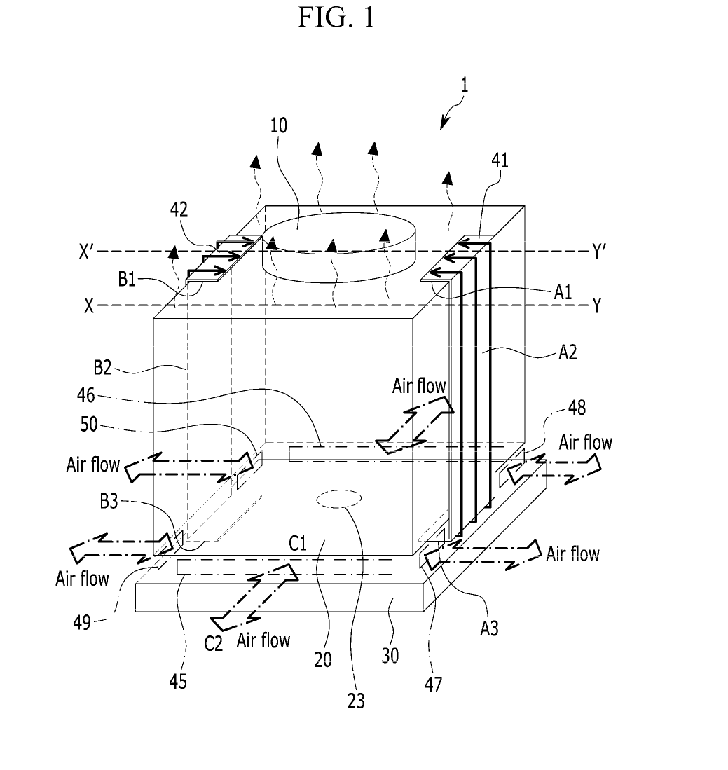

FIG. 1 is a cooling device according to a first exemplary embodiment of the present invention.

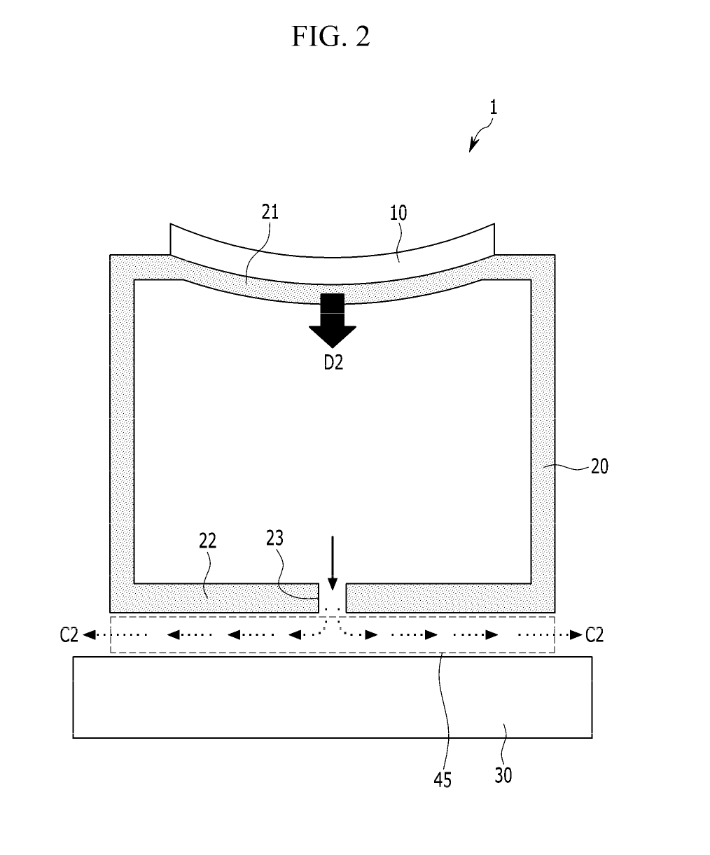

FIG. 2 is a cross-sectional view of the cooling device of FIG. 1, taken along the line X-Y, and illustrates air flow emitted from the cooling device.

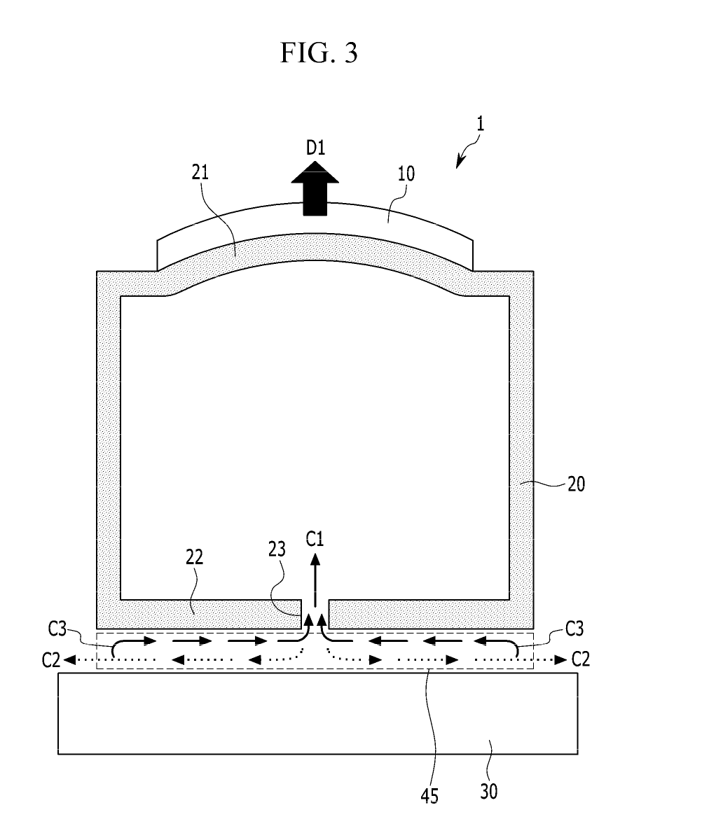

FIG. 3 is a cross-sectional view of the cooling device of the first exemplary embodiment of the present invention, taken along the line X-Y of FIG. 1, and illustrates air circulation of the cooling device.

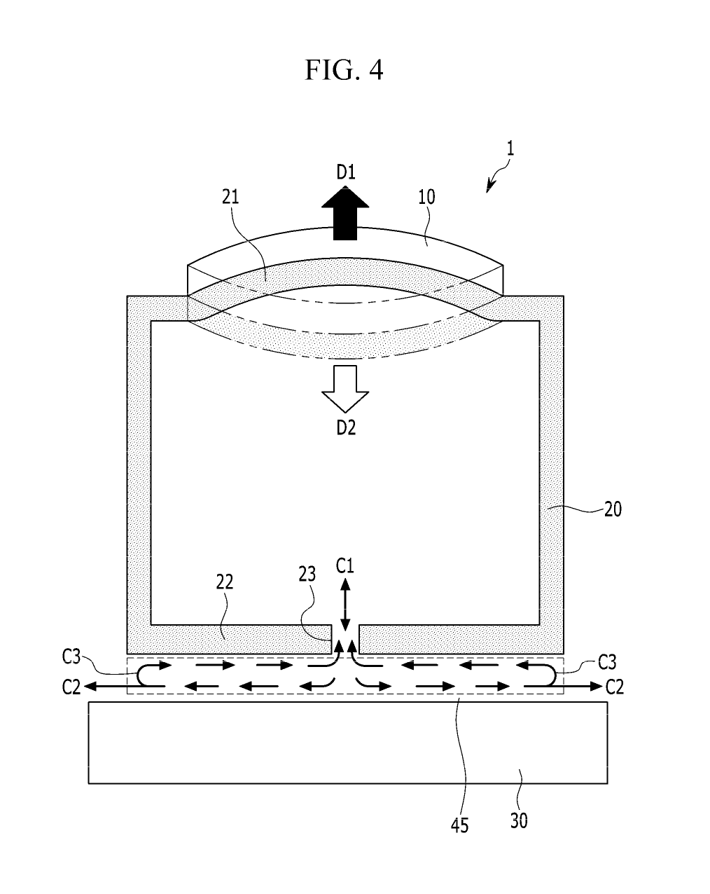

FIG. 4 is a cross-sectional view of the cooling device of the first exemplary embodiment of the present invention, taken along the line X-Y of FIG. 1, and illustrates air flow of the cooling device.

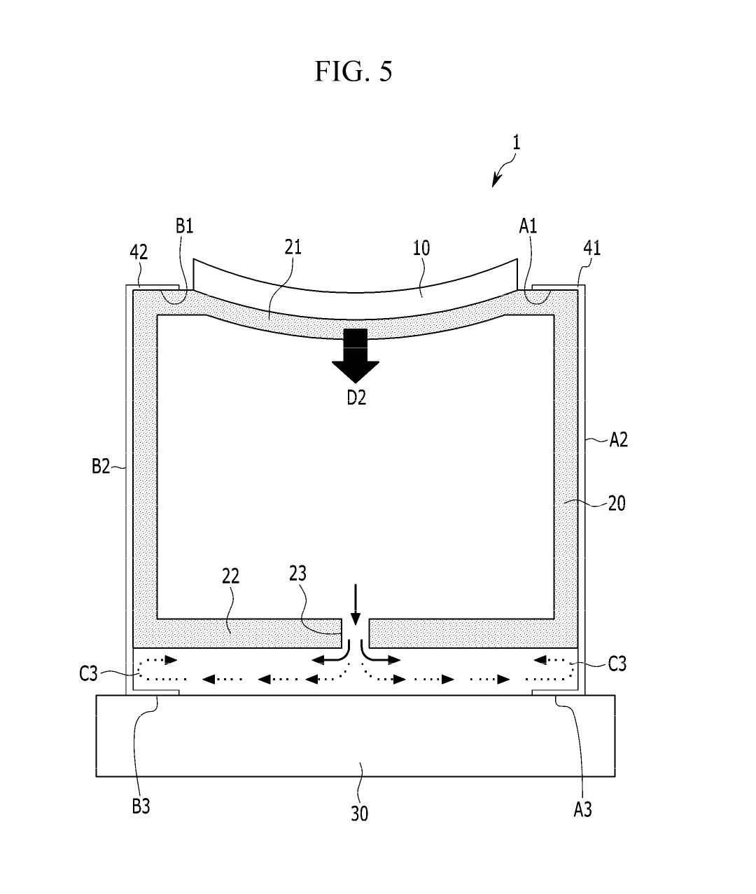

FIG. 5 is a cross-sectional view of FIG. 1, taken along the line X′-Y′, and illustrates air circulation of the cooling device according to the first exemplary embodiment of the present invention.

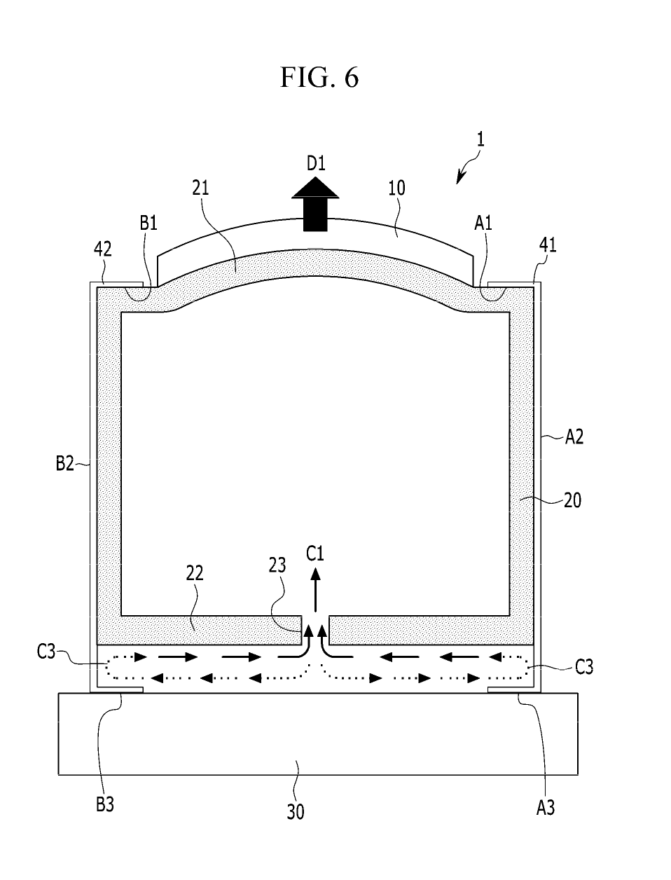

FIG. 6 is a cross-sectional view of FIG. 1, taken along the line X′-Y′, and illustrates air circulation of the cooling device according to the first exemplary embodiment of the present invention.

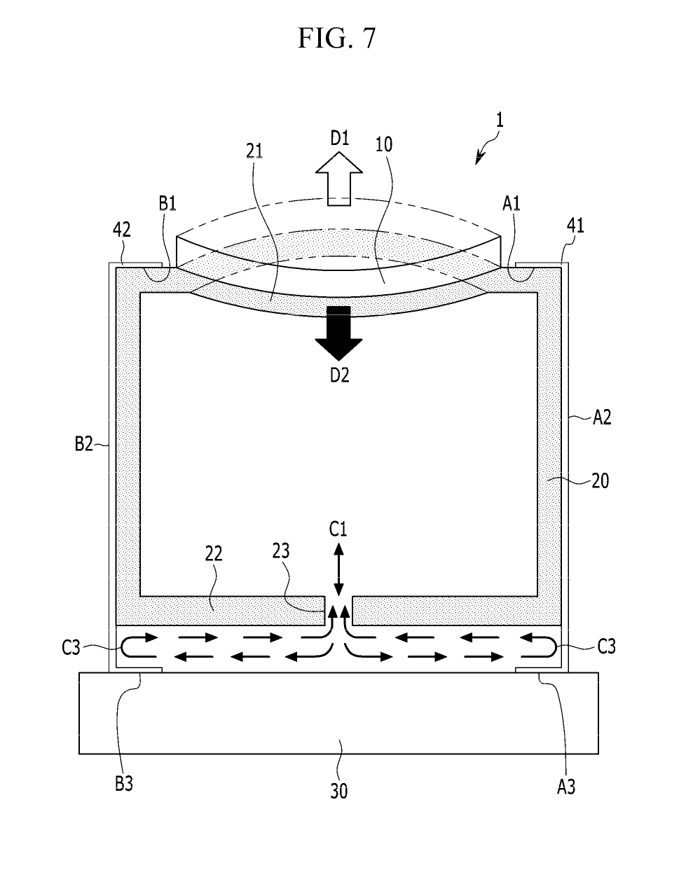

FIG. 7 is a cross-sectional view of FIG. 1, taken along the line X′-Y′, and illustrates air flow of the cooling device according to the first exemplary embodiment of the present invention.

Hereinafter, a cooling device according to the first exemplary embodiment of the present invention will be described with reference to FIG. 1 to FIG. 7.

A cooling device 1 according to the first exemplary embodiment of the present invention may be used in various embedded environments including a printed circuit board assembly (PCA) having a plurality of electronic elements to be cooled. The PCA implies various small-sized electronic devices such as a single board computer, a programmable logic controller (PLC), a lap-top computer, a portable telephone, a personal digital assistant (PDA), a personal pocket computer, and the like. The cooling device 1 according to the first exemplary embodiment of the present invention may be used in a heated environment in the PCA, and the size of the cooling device 1 may be properly set for an embedded environment to be used.

The cooling device 1 according to the first exemplary embodiment of the present invention includes a piezoelectric element 10, a chamber 20, an opening 23, and a first connection unit.

The piezoelectric element 10 may be an electric piezoelectric element using a piezoelectric feature of a ceramic material. The electric piezoelectric element is bendable up and down according to a polarity of an electric signal, and displacement of the bending may be changed in proportion to intensity of the electric signal. The piezoelectric element 10 may form stress derived from electric stimulation. As a proper material of the piezoelectric element 10, any element that performs reciprocating bending movement from one side to the other side due to electric stimulation, such as a piezoelectric material, a magnetostrictive material (i.e., magnetic fields from a coil pull each other or repel each other), a shape memory alloy, a motor imbalance (a motor having a mass imbalance that generates bending movement), and the like may be used. In a subset of the piezoelectric material, a proper piezoelectric material may include a bimorph piezoelectric configuration in which two piezo layers are activated due to a phase difference and thus generate bending, a thunder configuration in which a single piezo layer is provided on a stainless steel shim to which a stress is applied in advance, a buzzer element configuration in which a single piezo layer is provided on a brass shim, an MFC configuration in which a piezo fiber composite material on a flexible circuit is attached to a shim, and the like.

The cooling device 1 may include an electric circuit (not shown) providing an electric signal to the piezoelectric element 10. One surface 21 of a chamber may be bent toward a first direction D1 or a second direction D2 by the piezoelectric element 10 according to an electrical signal of the electric circuit, and thus electrical energy is changed to mechanical energy. The electrical signal may be provided as a sine wave, a square wave, a triangle wave, or other random waveform, and the electrical signal is not limited to a specific waveform. Like a sine wave, an electrical signal having lower harmonics may be used to provide a more silent chamber 20. A voltage level with respect to a current of the electrical signal may be included in a range from 1 volt to 150 volts, but it is not restrictive. A current frequency may be 2 Hz to 300 Hz in an exemplary embodiment in which a reduced noise level is required, and may be 300 Hz to 15 kHz in an exemplary embodiment in which a reduced noise level is not required.

The piezoelectric element 10 may be formed in plural in any surface of the chamber 20 or may be formed in each of the plurality of surfaces of the chamber 20. The piezoelectric element 10 may be formed in a bottom surface of the chamber 20, that is, a surface where the opening 23 is formed. The chamber 20 may be formed of a flexible material only at a surface where the piezoelectric element 10 is attached, and may be formed of a flexible material in other surfaces where the piezoelectric element 10 is not attached.

In addition, the piezoelectric element 10 may supply a sucking-in air flow C1 and a blowing-out air flow C2 of a heat source 30 by iteratively performing receiving and not receiving an air flow through an additional air flow supply pipe (not shown) from an external air flow generator (not shown).

The chamber 20 includes at least one surface. One surface 21 of the chamber 20 may be made of a flexible material such as a metal, a foil, a plastic, or a polymer composite material, and the chamber 20 may be formed of a thermally conductive material. The chamber 20 is formed in the shape of a quadrangle having a first surface 21 (i.e., an upper surface), a second surface 22 (a bottom surface), and a pair of walls that are perpendicular to the one surface 21 and the other surface 22 and facing each other, but is not restrictive.

Referring to FIG. 1 to FIG. 7, the piezoelectric element 10 is attached to the first (upper) surface 21 of the chamber 20, and at least one opening 23 is formed in the second (lower) surface 22. The chamber 20 is provided in an upper surface 21 of the heat source 30, and the opening 23 is provided in the bottom surface 22 of the chamber 20 so as to support the heat source 30. The piezoelectric element 10 receives the electrical signal and generates stresses in a first direction D1 and a second direction D2, and the first surface 21 of the chamber 20 is bent in the first direction D1 and the second direction S2 due to the stress such that an interior volume of the chamber 20 is changed. Due to the volume change of the chamber 20, an air flow may be generated through the opening 23.

The opening 23 is oriented toward the heat source 30 so as to provide an air flow path between the chamber 20 and the heat source 30. One or more openings 23 may be provided at one or more of the plurality of surfaces of the chamber 20. In FIG. 1 to FIG. 7, the opening 23 is oriented in a vertical direction from an upper portion of the heat source 30, and thus provides a vertical directional air flow path, but this is not restrictive. A direction of the opening 23 may form various angles with the heat source 30 such that the air flow path may be provided in various directions including a perpendicular direction, oblique directions with various slopes, and the like.

Although FIG. 1 to FIG. 7 illustrate that a single opening 23 is formed in the second surface 22 of the chamber 20, the present invention is not limited thereto, and the chamber 20 may include a plurality of openings.

Referring to FIG. 1 to FIG. 7, first connection units 41 and 42 made of a thermally conductive material are provided for a physical connection between the chamber 20 and the heat source 30, support between the chamber 20 and the heat source 30, and effective thermal conductivity between the chamber 20 and the heat source 30.

The first connection unit 41 includes a first member A1 contacting and connected in parallel with the upper portion of the chamber 20, a second member A1 vertically connected with the first member A1 and parallel with one side surface of the chamber 20, and a third member A3 vertically connected with the second member A2 and formed in one side of the upper portion of the heat source 30 or the bottom surface of the chamber 20. Here, the first member A1 is provided in one side of the upper portion of the chamber 20. The third member A3 may contact or be connected in parallel with the upper surface or the bottom surface of the chamber 20.

The second member A2 may contact one side of the chamber 20 or may be separated by a distance therefrom. When the second member A2 contacts one side of the chamber 20 and is then fixed thereto, the first member A1 may be omitted.

In another exemplary embodiment, the connection unit 41 may include a first member A1 contacting and connected with one side of the upper surface of the chamber 20 in parallel in one side of the upper surface of the chamber 20, and a second member A2 perpendicularly connected with the first member A1 and formed in parallel with a perpendicular direction to one side of the chamber 20. In this case, the second member A2 may be directly connected to one side of the heat source 30. By the connection units 41 and 42, air outlets 45 to 50 through which an air flow is blown out may be formed in a space between the connection units 41 and the connection unit 42 between the chamber 20 and the heat source 30.

Heat of the heat source 30 is conducted to the chamber 20 through the first connection units 41 and 42, and the conducted heat is discharged from the chamber 20 such that the heat source 30 may be cooled. The air flow generated due to the volume change of the chamber 20 is supplied to the heat source 30 so that the heat of the heat source 30 may be emitted. External air and internal air of the chamber 20 circulate through the first connection unit 41 and thus the air flow reaches the heat source 30 so that the heat of the heat source 30 can be emitted.

The air flow may include a sucking-in air flow C1 where air outside of the chamber 20 is sucked into the chamber 20 and a circulation air flow C3 circulating in a space formed in the bottom surface 22 of the chamber 20, the second member A2, and the upper surface 21 of the heat source 30 in a direction flowing into the chamber 20.

In detail, referring to FIG. 1 and FIG. 2, a negative electrical signal is applied to the piezoelectric element 10 and thus the first surface 21 of the chamber 20 may be bent due to the stress of the second direction D2. As the first surface 21 of the chamber 20 is bent toward the second direction D2, the total volume of the chamber 20 is reduced. Then, the internal air of the chamber 20 generates an air flow C2 that blows out through air outlets 47 and 48 formed between the air outlet 45 and the second member A2. When the blowing-out air flow C2 reaches the chamber 20 and the heat source 30, the heat of the heat source 30 may be cooled.

Referring to FIG. 1 and FIG. 3, a positive electrical signal is applied to the piezoelectric element 10 and thus the first surface 21 of the chamber 20 may be bent due to the stress of the first direction D1. As the first surface 21 of the chamber 20 is bent toward the first direction D1, the total volume of the chamber 20 is increased. Then, the external air flows into the chamber 20 through the air outlet 45 formed in the chamber 20, and a part of the blowing-out air flow C2 may not be emitted to the outside of the chamber 20 due to the stress of the first direction D1 so that the circulation air flow C3 may be formed. The external air flown into the chamber 20 and the circulation air flow C3 reach the heat source 30, the chamber 20, and the second members A2 and B2, and thus the heat of the heat source 30 can be cooled.

Referring to FIG. 1 to FIG. 4, the electrical signal of the piezoelectric element 10 is applied with a short cycle so that the first surface 21 of the chamber 20 may also be bent toward the first direction D1 and the second direction D2 with a short cycle. Accordingly, the internal air of the chamber 20 may form the blowing-out air flow C2 and the circulation air flow C3.

Referring to FIG. 1 to FIG. 5, the negative electrical signal is applied to the piezoelectric element 10, and thus the first surface 21 of the chamber 20 may be bent due to the stress of the second direction D2. As the first surface 21 of the chamber 20 is bent toward the second direction D2, the total volume of the chamber 20 is reduced. Then, a part of the internal air of the chamber 20 may form the circulation air flow C3 by being blocked by the second members A2 and B2. When the circulation air flow C3 reaches the heat source 30, the chamber 20, and the second members A2 and B2, the heat of the heat source 30 may be cooled.

Referring to FIG. 1 to FIG. 6, the positive electrical signal is applied to the piezoelectric element 10 and thus the first surface 21 of the chamber 20 may be bent toward the first direction D1. As the first surface 21 of the chamber 20 is bent to the first direction D1, the total volume of the chamber 20 is increased. Then, the circulation air flow C3 may generate the sucking-in air flow C1 flown into the chamber 20. When the sucking-in air flow C1 and the circulation air flow C3 reach the heat source 30, the chamber 20, and the second members A2 and B2, the heat of the heat source 30 can be cooled.

Referring to FIG. 1 to FIG. 7, the electrical signal is applied to the piezoelectric element 10 with a very short cycle so that the first surface 21 of the chamber 20 also can be bent to the first direction D1 and the second direction D2 with a short cycle. Accordingly, the sucking-in air flow C1 and the circulation air flow C3 can be generated.

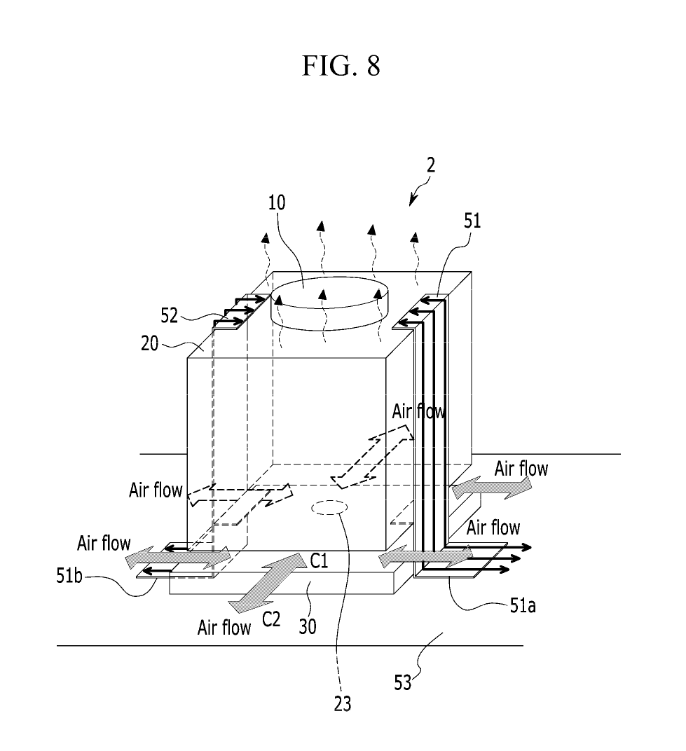

FIG. 8 illustrates a cooling device according to a second exemplary embodiment of the present invention.

Hereinafter, the cooling device according to the second exemplary embodiment of the present invention will be described with reference to FIG. 8.

Compared to the first exemplary embodiment of the present invention, the shape of first connection units are different from that of second connection units 51 and 52 in the second exemplary embodiment of FIG. 8. The same reference numerals designate the same elements in the previous exemplary embodiment, and a detailed description thereof will be omitted hereinafter.

A cooling device 2 according to the second exemplary embodiment of the present invention includes a piezoelectric element 10, a chamber 20, an opening 23, and the second connection unit 51 and 52.

The second connection unit 52 and the second connection unit 51 are horizontally symmetrical to each other, and are respectively attached to a side surface of the heat source 30 and a substrate 53 to which the heat source 30 is attached such that heat of the heat source 30 and the substrate 53 can be conducted to the chamber 20.

The substrate 53 is one example of a structure that is electrically or mechanically connected with the heat source 30.

Referring to FIG. 8, the second connection unit further includes substrate attachment surfaces 51a and 51b formed in a “ [symbol] ” shape in a lower portion of the first connection unit 41 of FIG. 1, and the substrate attachment surfaces 51a and 51b are respectively attached to the side surface of the heat source 30 and the substrate 30 to which the heat source 30 is attached so that the heat of the heat source 30 and the substrate 53 can be conducted to the chamber 20.

The heat of the heat source 30 and the heat of the substrate 53 may be emitted through the second connection units 51 and 52. In addition, the heat of the heat source 30 and the heat of the substrate 53 may be conducted from the upper surface of the chamber 20 through the second connection units 51 and 52, and the conducted heat may be emitted through the chamber 20.

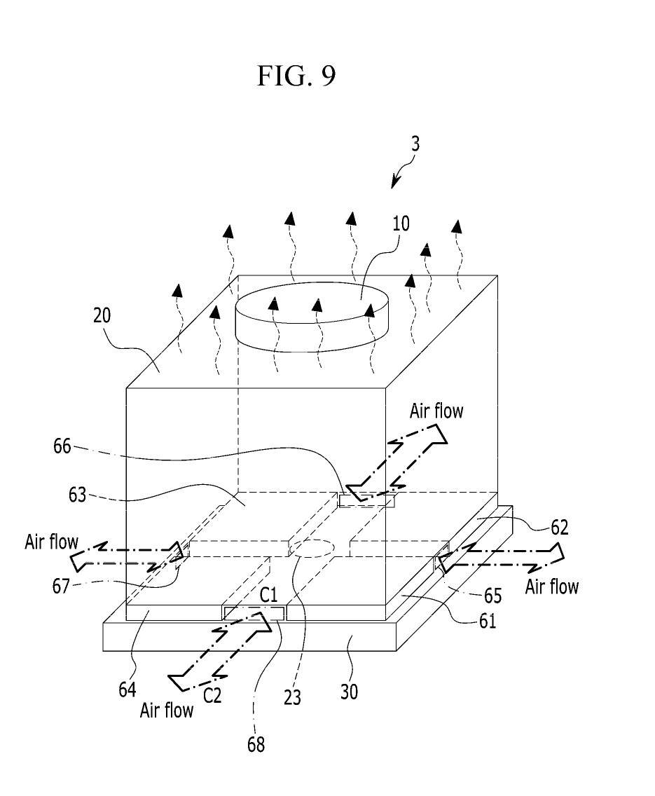

FIG. 9 shows a cooling device according to a third exemplary embodiment of the present invention.

Hereinafter, the cooling device according to the third exemplary embodiment of the present invention will be described with reference to FIG. 9.

Compared to the first exemplary embodiment, the shape of connection units 61 to 64 are different from each other in the third exemplary embodiment of the present invention. The same reference numerals designate the same elements in the previous exemplary embodiment, and a detailed description thereof will be omitted hereinafter.

The cooling device 3 according to the third exemplary embodiment of the present invention includes a piezoelectric element 10, a chamber 20, an opening 23, and the plurality of third connection units 61 to 64.

Referring to FIG. 9, the plurality of third connection units 61 to 64 are respectively provided between a bottom surface of the chamber 20 and an upper surface of the heat source 30, and thus may bond the chamber 20 and the heat source 30 to each other.

One side surface of the chamber 20 and one side surface of the heat source 30 corresponding to the surface of the chamber 20 may be provided in the same location or different locations along a vertical direction.

Each of the plurality of third connection units 61 to 64 is formed as a tape made of a thermally conductive material, and heat of the heat source 30 may be conducted to the chamber 20 through each of the plurality of third connection units 61 to 64. One side surface of each of the plurality of third connection units 61 to 64, which are exposed to the outside between the chamber 20 and the heat source 30, may be provided in the same location as the side surface of the chamber 20 of the side surface of the heat source 30 in the vertical direction.

The plurality of third connection units 61 to 64 may protrude more by a predetermined length than the side surface of the chamber 20 or the side surface of the heat source 30. Air outlets 65 to 67 through which an air flow can be emitted may be formed between the respective third connection units 61 to 64.

FIG. 9 illustrates that each of the plurality of third connection units 61 to 64 is provided in each corner of the heat source 30, but this is not restrictive.

Referring to FIG. 9, the plurality of third connection units 61 to 64 are formed in the shape of a quadrangle, but this is not restrictive. The plurality of third connection units 61 to 64 may have various shapes such as a triangle, a circle, and the like.

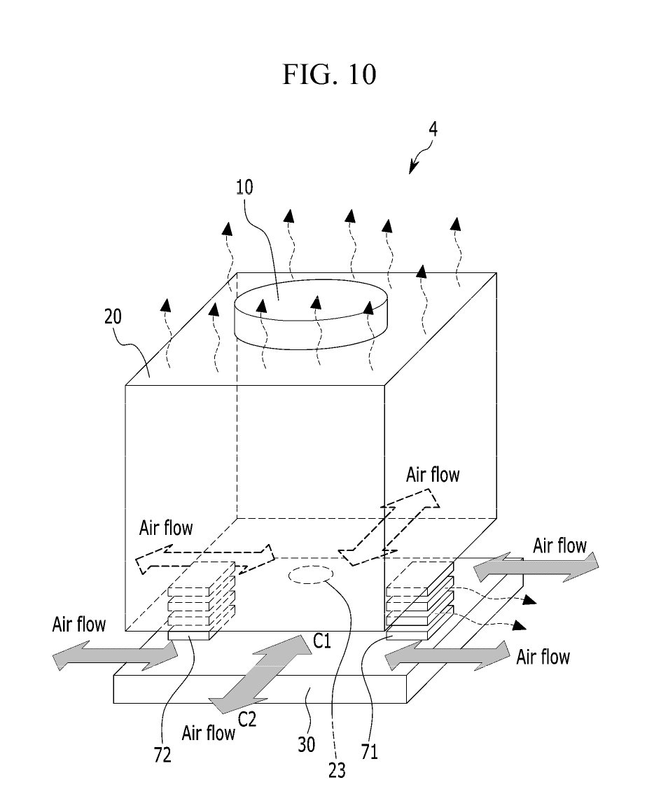

FIG. 10 illustrates a cooling device according to a fourth exemplary embodiment of the present invention.

Hereinafter, a cooling device according to the fourth exemplary embodiment of the present invention will be described with reference to FIG. 10.

The fourth exemplary embodiment of FIG. 10 differs from the first exemplary embodiment in that fourth connections 71 to 74 respectively have different shapes. The same reference numerals designate the same elements in the previous exemplary embodiment, and a detailed description thereof will be omitted hereinafter.

A cooling device 4 according to the fourth exemplary embodiment of the present invention includes a piezoelectric element 10, a chamber 20, an opening 23, and the fourth connection units 71 and 72.

Referring to FIG. 10, the fourth connection units 71 and 72 are formed in the shape of a circular or polygonal pillar, and protrusions and depressions may be formed in an external surface of the fourth connection units 71 and 72. The protrusions and depressions may also be formed in the exposed surfaces of the above-stated first to third connection units. In addition, the fourth connection units 71 and 72 may be provided between a bottom surface of the chamber 20 and an upper surface of the heat source 30.

Air outlets through which an air flow can be emitted may be formed between the respective fourth connection units 71 and 72 by the fourth connection units 71 and 72.

Heat of the heat source 30 may be emitted through the protrusions and depressions of the fourth connection units 71 and 72 and the chamber 20.

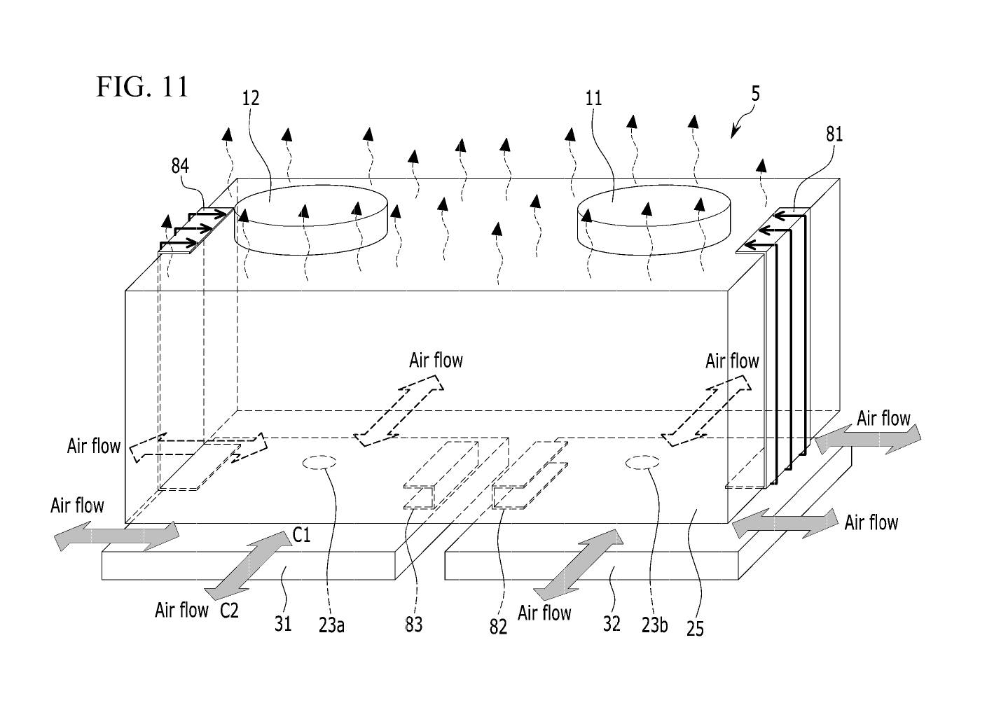

FIG. 11 illustrates a cooling device according to a fifth exemplary embodiment of the present invention.

Hereinafter, a cooling device according to the fifth exemplary embodiment of the present invention will be described with reference to FIG. 11.

A cooling device 5 according to the fifth exemplary embodiment of the present invention may include a plurality of fifth connection units 81 to 84 that correspond to the first connection units 41 and 42. The same reference numerals designate the same elements in the previous exemplary embodiment, and a detailed description thereof will be omitted hereinafter.

The cooling device 5 according to the fifth exemplary embodiment of the present invention includes a plurality of piezoelectric elements 11 and 12 corresponding to a plurality of heat sources 31 and 32, a chamber 25, a plurality of openings 23a and 23b, and a plurality of fifth connection units 81 to 84. The same reference numerals designate the same elements in the previous exemplary embodiment, and a detailed description thereof will be omitted hereinafter.

As shown in FIG. 11, two heat sources 31 and 32 are provided in the fifth exemplary embodiment of the present invention, but this is not restrictive, and two or more heat sources 30 may be provided in the fifth exemplary embodiment of the present invention. For example, the chamber 25 is extended along an alignment direction of the heat sources according to the number of heat sources, and a plurality of openings may be provided in the extended chamber 25 corresponding to the plurality of heat sources.

Thus, a plurality of air flow paths corresponding to the plurality of openings may be provided.

Referring to FIG. 11, the fifth connection unit 82 is attached between one surface of the heat source 32 and a bottom surface of the chamber 25. The fifth connection unit 83 is attached between one surface of the heat source 31 and the bottom surface of the chamber 25. In addition, the shape of the fifth connection units 82 and 83 is not limited to the shape shown in FIG. 7, and may be formed in the shape shown in FIG. 4 or FIG. 5.

A single space may be formed in the chamber 25, or two distinctive spaces may be formed respectively corresponding to locations of the heat sources 31 and 32.

The opening of the chamber 25 may be formed corresponding to locations of the piezoelectric elements 11 and 12. For example, the two openings 23a and 23b may be formed in the bottom surface of the chamber 23 respectively corresponding to the locations of the piezoelectric elements 11 and 12. The locations and numbers of the openings 23a and 23b are set for generation of air flow according to voltages applied to the piezoelectric elements 11 and 12, and are not limited to the present exemplary embodiment of the present invention.

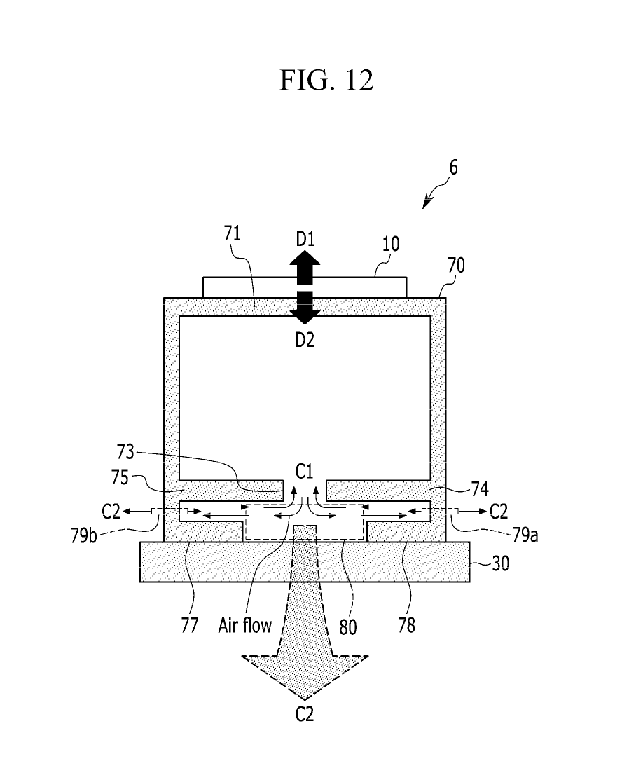

FIG. 12 shows a cooling device according to a sixth exemplary embodiment of the present invention.

Hereinafter, a cooling device according to the sixth exemplary embodiment of the present invention will be described with reference to FIG. 12.

The chamber 27 of the sixth exemplary embodiment of the present invention is different from the chamber 20 of the first exemplary embodiment of the present invention in shape. The same reference numerals designate the same elements in the previous exemplary embodiment, and a detailed description thereof will be omitted hereinafter.

A cooling device 6 according to the sixth exemplary embodiment of the present invention includes a piezoelectric element 10, a chamber 70, and an opening 73.

Referring to FIG. 12, the chamber 70 has a structure in which the chamber 70 of FIG. 1 is integrally formed with the first connections 41 and 42. The piezoelectric element 10 is attached to one surface 71 of the chamber 70, and members 77 and 78 provided in a lower portion of the chamber 70 contact a heat source 30. The opening 73 is provided between the surface 71 and the members 77 and 78.

Although it is illustrated in FIG. 12 that the members 77 and 78 are formed in a shape that is oriented to the opening 73, the present exemplary embodiment is not limited thereto. The members 77 and 78 may have various shapes for convenience in transmission of heat of the heat source 30 to the chamber 70.

In detail, the members 77 and 78 may be oriented in a direction that faces the outer side of the chamber 70.

In addition, the chamber 70 may further include the substrate attachment surfaces 51a and 51b and be integrally formed with the substrate attachment surfaces 51a and 51b so that heat of the substrate 53 can be conducted to the chamber 70. Side surfaces 74 and 75 of the chamber 70 may include at least one of air holes 79a and 79b through which an air flow of the chamber 70 flows.

External air of the chamber 70 and internal air of the chamber 70 circulate through the opening 73, the air holes 79a and 79b, and an air outlet 80 formed between the members 77 and 78 such that the air flow is formed. The circulating air flow includes a sucking-in air flow C1 and a blowing-out air flow C2, and the heat of the heat source 30 may be cooled by the sucking-in air flow C1 or may be emitted by the blowing-out air flow C2.

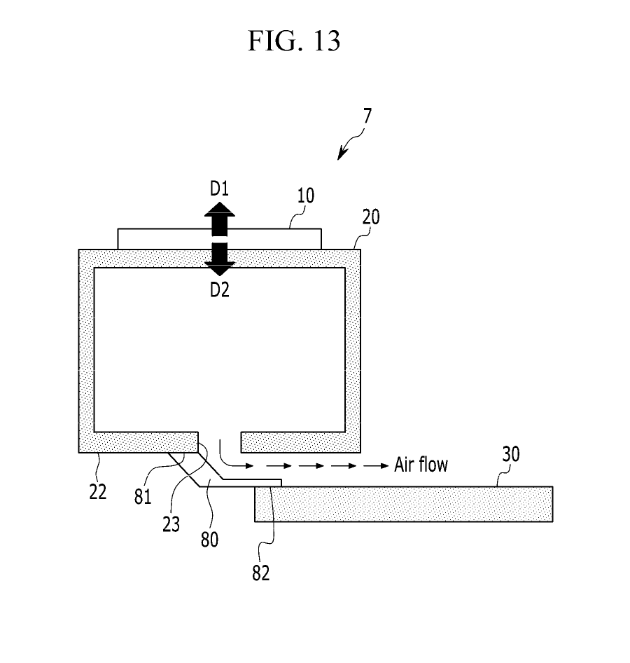

FIG. 13 is a cross-sectional view of a cooling device according to a seventh exemplary embodiment of the present invention.

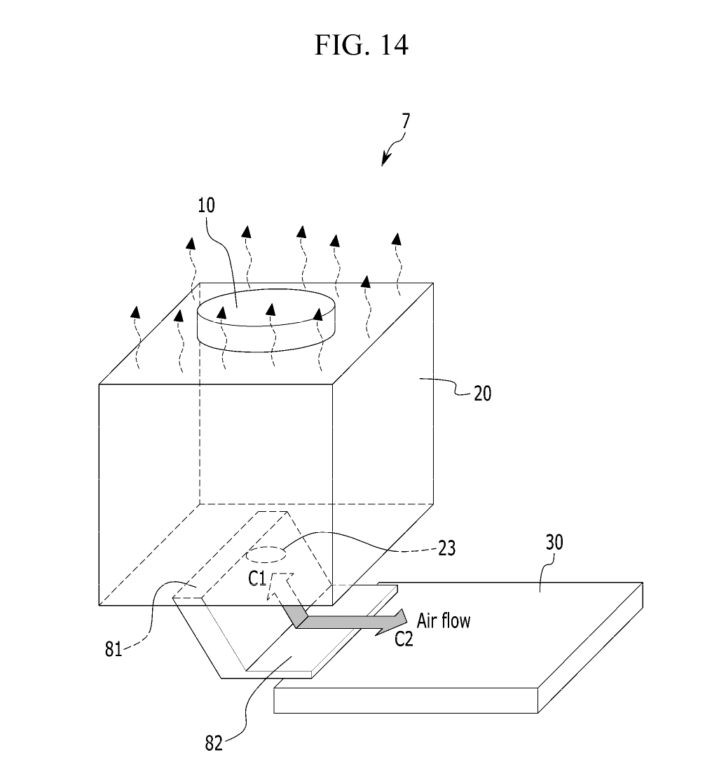

FIG. 14 is a perspective view of the cooling device according to the seventh exemplary embodiment of the present invention.

Hereinafter, a cooling device according to the seventh exemplary embodiment of the present invention will be described with reference to FIG. 13 and FIG. 14.

Compared to the cooling device 1 of the first exemplary embodiment of the present invention, a sixth connection unit 80 of a cooling device 7 according to the seventh exemplary embodiment of the present invention is different from that of the cooling device 1 in shape. The same reference numerals designate the same elements in the previous exemplary embodiment, and a detailed description thereof will be omitted hereinafter.

The cooling device 7 according to the seventh exemplary embodiment of the present invention includes a piezoelectric element 10, a chamber 20, an opening 23, and the sixth connection unit 80.

Referring to FIG. 13 and FIG. 14, the sixth connection unit 80 may form a flow path of an air flow through the opening 23.

In detail, the sixth connection unit 80 includes a third member 81 contacting a bottom surface 22 of the chamber 20 and a fourth member 82 attached to an upper portion of the heat source 30, and may form a flow path for conducting an air flow to the upper portion of the heat source 30. The sixth connection unit 80 may be made of a thermally conductive material.

The flow path may form an air flow path to a direction of a sucking-in air flow C1 and a direction of a blowing-out air flow C2.

The sucking-in air flow C1 is an air flow of the external air of the chamber 20 flowing into the chamber 20 through the sixth connection unit 80. The sucking-in air flow C1 reaches the heat source 30 through an air flow path formed along the flow path such that the heat source 30 can be cooled by the external air.

The blowing-out air flow C2 is an air flow of the internal air of the chamber 20 blowing out of the chamber 20 through the sixth connection unit 80. The blowing-out air flow reaches the heat source 30 along the air flow path formed along the flow path, and emits heat of the heat source 30 to the outside.

Although it is illustrated in FIG. 13 and FIG. 14 that the sixth connection unit 80 has a bent shape including a corner in a middle thereof, but the present exemplary embodiment is not limited thereto. The sixth connection unit 80 may have various shapes. In detail, the sixth connection unit 80 may form a flow path that is perpendicular or oblique to the heat source 30 rather than having a bent shape, and the sixth connection unit 80 may also form a bent flow path including a curved side.

In addition, although it is illustrated in FIG. 13 and FIG. 14 that only one heat source 30 is included in the seventh exemplary embodiment, the present invention is not limited thereto. Two or more heat sources 30 may be applied to the seventh exemplary embodiment of the present invention. For example, the chamber 20 may be extended along a direction in which a plurality of heat sources 30 are arranged, and the extended chamber 20 may include a plurality of sixth connection units 80 including a flow path that is oriented to each of the plurality of heat sources 30.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of Symbols>

| | |
|---|---|
| 10: piezoelectric element | 20: chamber |
| 23: opening | 30: heat source |
| 41, 42: first connection unit | A1, B1: first member |
| A2, B2: second member | A3, B3: third member |

What is claimed is:

1. A cooling device comprising:
a chamber including at least one flexible surface;
a piezoelectric element formed in the at least one flexible surface, the piezoelectric element being to generate a volume change in the chamber by bending the at least one flexible surface in a first direction or a second direction to generate a first directional air flow or a second directional air flow;
an opening formed in a second surface of the chamber to provide a channel for the first direction air flow or the second directional air flow; and
at least one connection unit to connect an outer side of the chamber to a heat source that is provided at a distance from the chamber.

2. The cooling device of claim 1, wherein the first directional air flow and the second directional air flow comprise a circulation air flow circulating between the chamber and the heat source and cooling heat of the heat source by reaching the chamber, the connection unit, and the heat source.

3. The cooling device of claim 2, wherein the connection unit comprises at least two connection members and an air outlet formed between the at least two connection members through which the heat of the heat source is emitted.

4. The cooling device of claim 1, wherein the connection unit comprises protrusions and depressions formed in a surface exposed to the outside.

5. The cooling device of claim 1, wherein the connection unit is made of a thermally conductive material.

6. The cooling device of claim 1 wherein the piezoelectric element is an electric piezoelectric element using a piezoelectric characteristic of a ceramic material to cause the at least one flexible surface to bend in the first direction or the second direction based on a polarity of an electric signal.

7. The cooling device of claim 1, wherein the opening is formed in parallel with the heat source.

8. The cooling device of claim 3, wherein each of the at least two connection members comprise a first member contacting an upper end of the chamber and a second member extended perpendicularly from at least one of the at least two connection members and contacting one surface of the heat source.

9. The cooling device of claim 8, wherein the second member is separated from or contacts one surface of the chamber.

10. The cooling device of claim 8, comprising a third member perpendicularly connected with the second member and contacting an upper surface or a bottom surface of the heat source.

11. The cooling device of claim 10, wherein the connection unit further comprises a substrate attachment surface to attach to a substrate that includes the heat source and a fourth member extended to the substrate attachment surface and contacts the substrate attachment surface.

12. The cooling device of claim 1, wherein the cooling device comprises:
at least two piezoelectric elements;
a chamber formed of a plurality of surfaces that include a flexible first surface where the at least two piezoelectric elements are formed and a second surface where at least two openings are formed corresponding to locations of the at least two piezoelectric elements; and
at least two connection units to connect the chamber to at least one outer side of at least two heat sources, heat from the at least two heat sources being conducted to the chamber by the at least two connection units, wherein the first directional air flow and the second directional air flow are formed by the at least two piezoelectric elements and supplied to the heat source through the at least two openings, and further wherein a part of the at least two connection units comprises a first member connecting an upper end of the chamber and a second member perpendicularly extended from the first member and contacts at least one surface of the at least two heat sources.

13. The cooling device of claim 12, wherein the connection unit is made of a thermally conductive material,
heat from the at least two heat sources being conducted to the chamber through the at least two connection units and emitted through the at least two connection units and the chamber, and
the first directional air flow and the second directional air flow emit heat of the heat source by circulating between the at least two connection units.

14. The cooling device of claim 13, wherein the chamber comprises at least two distinctive spaces respectively corresponding to locations of the at least two heat sources.

15. The cooling device of claim 12, wherein the connection unit is formed of an adhesive tape made of a thermally conductive material.

16. A cooling device comprising:
a chamber including at least one flexible surface;
a piezoelectric element formed in the at least one flexible surface, the piezoelectric element being to generate a volume change in the chamber by bending the at least one flexible surface in a first direction or a second direction to generate a first directional air flow or a second directional air flow;
an opening formed in a second surface of the chamber to provide a channel for the first direction air flow or the second directional air flow; and
at least one connection unit connected to an outer side of the chamber, the connection unit including:
a first member contacting an upper end of the chamber,
a second member perpendicularly extended from the first member and contacting one surface of a heat source, and
a flow path oriented to the heat source, wherein the flow path forms an air flow path between the chamber and the heat source.

17. The cooling device of claim 16, wherein the first directional air flow and the second directional air flow comprise a circulation air flow circulating between the chamber and the heat source and cooling heat of the heat source by reaching the chamber, the connection unit, and the heat source.

18. The cooling device of claim 17, wherein the connection unit is made of a thermally conductive material, heat from the heat source being conducted to the chamber through the connection unit, the heat being emitted through the connection unit and the chamber, and the first directional air flow or the second directional air flow is supplied to the heat source through the flow path.

19. The cooling device of claim 16, wherein the flow path is formed in parallel with the heat source, and the first directional air flow or the second directional air flow is supplied in a direction parallel to the heat source through the flow path.

20. The cooling device of claim 16 wherein the flow path is formed perpendicularly to the heat source, and the first directional air flow or the second directional air flow is supplied to the heat source in a perpendicular direction.

21. The cooling device of claim 16 wherein the flow path is formed oblique to the heat source, and the first directional air flow or the second directional air flow is supplied in an oblique direction to the heat source through the flow path.

22. The cooling device of claim 16 wherein the flow path comprises a corner, and the first direction air flow or the second directional air flow is supplied to the heat source through the flow path.

23. The cooling device of claim 16 wherein the flow path comprises a curved surface, and the first directional air flow or the second directional air flow is supplied to the heat source through the flow path.
